(19) United States
(12) Patent Application Publication
(10) Pub. No.: US 2025/0351479 A1
(43) Pub. Date: Nov. 13, 2025

(54) SEMICONDUCTOR DEVICE

(71) Applicant: Mitsubishi Electric Corporation, Tokyo (JP)

(72) Inventors: Tasuku SUMINO, Tokyo (JP); Satoshi SUZUKI, Tokyo (JP)

(73) Assignee: Mitsubishi Electric Corporation, Tokyo (JP)

(21) Appl. No.: 18/861,500

(22) PCT Filed: Oct. 19, 2022
(86) PCT No.: PCT/JP2022/038906

§ 371 Date: Oct. 29, 2024

(51) Int. Cl. H10D 62/10; H01L 23/00; H01L 23/482

(52) U.S. Cl. CPC H10D 62/117; H01L 23/4821; H01L 24/05; H01L 24/45; H01L 2224/05541; H01L 2224/05551; H01L 2224/05557; H01L 2224/4502; H01L 2924/30105; H01L 2924/386

(57) ABSTRACT

An epitaxial layer (2) is formed on a substrate (1). A field effect transistor (3) is formed on the epitaxial layer (2). A drain pad (8) is formed on the epitaxial layer (2). The drain pad (8) is connected to a drain electrode (5) of the field effect transistor (3). A back surface electrode (13) is formed on a back surface of the substrate (1) and connected to a source electrode (6) of the field effect transistor (3). A wire (16) is bonded to the drain pad (8). A cavity (17) is formed in the substrate (1) directly below the drain pad (8). The cavity (17) is not formed directly below a bonding portion of the wire (16).

### BACKGROUND OF THE INVENTION

### Field

The present disclosure relates to a semiconductor device.

### Background

In a field effect transistor, a source pad and a drain pad are formed on a front surface side of a substrate, and a back surface electrode is formed on a back surface side of the substrate. The back surface electrode and the source pad are connected together by a via hole. The drain pad of the field effect transistor used for a high-output amplifier is largely formed because a plurality of wires are disposed so as to allow a large current to flow. A large parasitic capacitance is formed between the drain pad on the front surface side and an n-type semiconductor substrate on the back surface side or the back surface electrode. A technique has been suggested in which in order to reduce this parasitic capacitance, a cavity is formed below a drain pad by etching a substrate from a back surface (for example, see PTL 1).

### CITATION LIST

### Patent Literature

### SUMMARY OF THE INVENTION

### Problem to be Solved by the Invention

However, in related art, because a cavity is formed directly below bonding portions of wires, it has been difficult to secure strength for bearing an impact of wire bonding.

The present disclosure has been made for solving the above-described problem, and an object thereof is to obtain a semiconductor device that can bear an impact of wire bonding while reducing a parasitic capacitance.

### Solution to Problem

A semiconductor device according to the present disclosure includes: a substrate; an epitaxial layer formed on the substrate; a field effect transistor formed on the epitaxial layer; a drain pad formed on the epitaxial layer and connected to a drain electrode of the field effect transistor; a back surface electrode formed on a back surface of the substrate and connected to a source electrode of the field effect transistor; and a wire bonded to the drain pad, wherein a cavity is formed in the substrate directly below the drain pad, and the cavity is not formed directly below a bonding portion of the wire.

### Advantageous Effects of Invention

In the present disclosure, the cavity is formed in the substrate directly below the drain pad. Consequently, without decreasing an area of the drain pad, the parasitic capacitance between the drain pad and the back surface electrode can be reduced. Further, the cavity is not formed directly below the bonding portion of the wire. Consequently, it is possible to bear the impact of wire bonding.

### BRIEF DESCRIPTION OF DRAWINGS

FIG. 1 is a plan view illustrating a semiconductor device according to a first embodiment.

FIG. 2 is a cross-sectional view taken along I-II in FIG. 1.

FIG. 3 is a cross-sectional view taken along III-IV in FIG. 1.

FIG. 4 is a cross-sectional view taken along V-VI in FIG. 1.

FIG. 5 is a cross-sectional view illustrating a semiconductor device according to the first comparative example.

FIG. 6 is a cross-sectional view illustrating a semiconductor device according to the second comparative example.

FIG. 7 is a plan view illustrating a semiconductor device according to a second embodiment.

FIG. 8 is a cross-sectional view taken along I-II in FIG. 7.

FIG. 9 is a plan view illustrating a semiconductor device according to a third embodiment.

FIG. 10 is a cross-sectional view illustrating a semiconductor device according to a fourth embodiment.

FIG. 11 is a cross-sectional view illustrating a semiconductor device according to a fifth embodiment.

### DESCRIPTION OF EMBODIMENTS

A semiconductor device according to the embodiments of the present disclosure will be described with reference to the drawings. The same components will be denoted by the same symbols, and the repeated description thereof may be omitted.

### First Embodiment

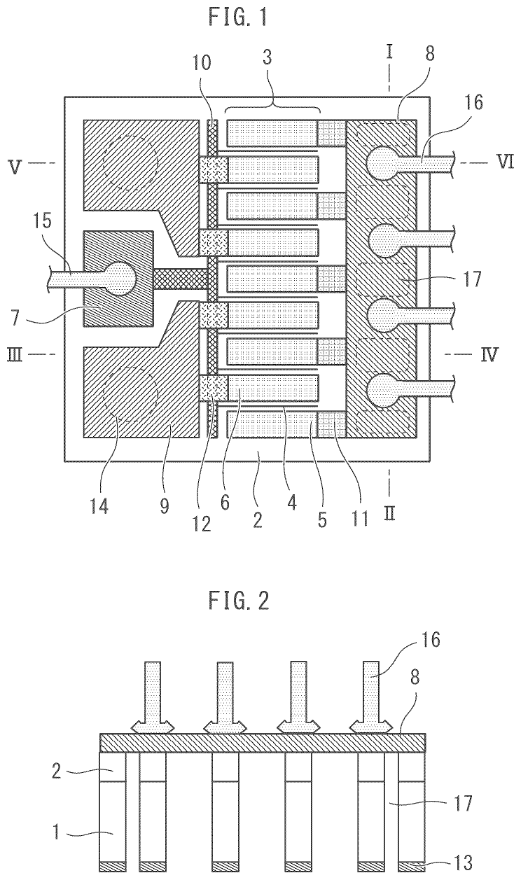

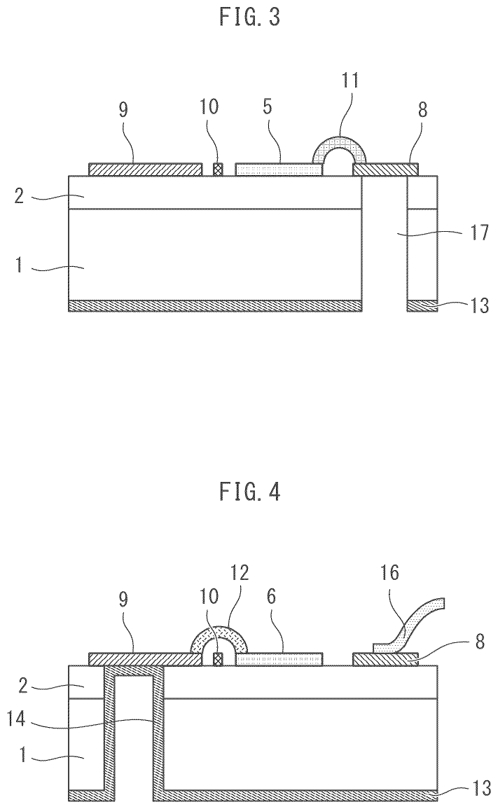

FIG. 1 is a plan view illustrating a semiconductor device according to a first embodiment. FIG. 2 is a cross-sectional view taken along I-II in FIG. 1. FIG. 3 is a cross-sectional view taken along III-IV in FIG. 1. FIG. 4 is a cross-sectional view taken along V-VI in FIG. 1.

An epitaxial layer 2 is formed on a substrate 1. The substrate 1 is a semi-insulating substrate formed of GaAs, SiC, InP, sapphire, GaN, diamond, or the like. A material of the epitaxial layer 2 is GaAs, GaN, or InP, for example. However, the substrate 1 may be an n-type semiconductor substrate formed of n-type silicon or the like, and in such a case, the epitaxial layer 2 is also formed of silicon.

A field effect transistor 3 is formed on the epitaxial layer 2. The field effect transistor 3 has a plurality of gate electrodes 4, a plurality of drain electrodes 5, and a plurality of source electrodes 6. Each of the gate electrodes 4 is arranged between the drain electrode 5 and the source electrode 6 which are adjacent to each other.

A gate pad 7, a drain pad 8, and source pads 9 are formed on the epitaxial layer 2. The gate pad 7 is connected to the plurality of gate electrodes 4 via gate wiring 10. The drain pad 8 is connected to the plurality of drain electrodes 5 via air-bridge wiring 11. The source pad 9 is connected to the plurality of source electrodes 6 via air-bridge wiring 12 across the gate wiring 10.

A back surface electrode 13 is formed on a back surface of the substrate 1. The back surface electrode 13 is connected to the source pad 9 via a via hole 14 which passes through the substrate 1 and the epitaxial layer 2. A wire 15 is bonded to the gate pad 7. A plurality of wires 16 are bonded to the drain pad 8. A size of each of bonding parts of the wires 15 and 16 is 50 to 60 μm.

The substrate 1 is etched from the back surface side, and a plurality of cavities 17 are thereby formed in the substrate 1 and the epitaxial layer 2 directly below the drain pad 8. A width of each of the cavities 17 is approximately 80 μm. The plurality of cavities 17 are not formed directly below bonding portions of the plurality of wires 16.

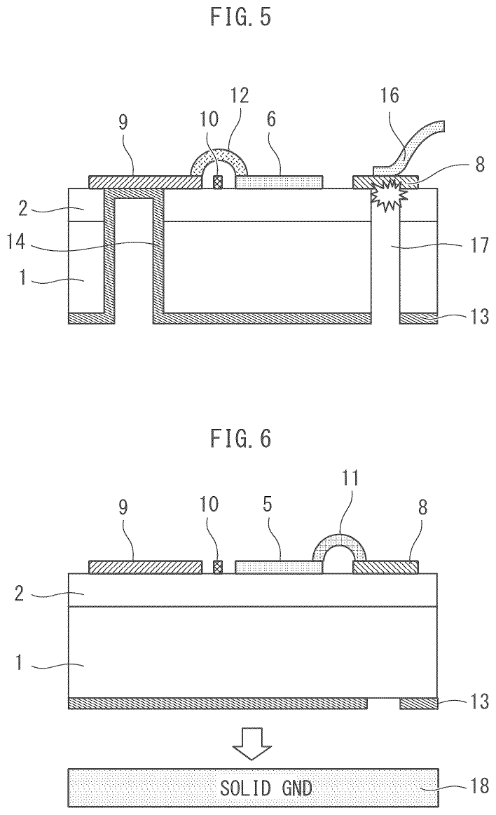

Next, effects of the present embodiment will be described by comparing that with first and second comparative examples. FIG. 5 is a cross-sectional view illustrating a semiconductor device according to the first comparative example. In the first comparative example, the cavity 17 is formed directly below the bonding portion of the wire 16. Thus, it is difficult to secure strength for bearing an impact of wire bonding. FIG. 6 is a cross-sectional view illustrating a semiconductor device according to the second comparative example. In the second comparative example, no cavity 17 is provided in the substrate 1, and a part of the back surface electrode 13 is removed directly below the drain pad 8. However, because the semiconductor device is mounted on a GND 18 of a package, a parasitic capacitance is generated between the drain pad 8 and the GND 18 of the package. Consequently, even when a part of the back surface electrode 13 is removed, the parasitic capacitance is hardly changed.

On the other hand, in the present embodiment, the cavity 17 is formed in the substrate 1 directly below the drain pad 8. An internal portion of the cavity 17 has air or a vacuum, and permittivity of the internal portion of the cavity 17 is smaller than that of the substrate 1. Consequently, without decreasing an area of the drain pad 8, the parasitic capacitance between the drain pad 8 and the back surface electrode 13 can be reduced.

Further, the cavity 17 is not formed directly below the bonding portion of the wire 16. Consequently, the thin drain pad 8 above the cavities 17 is not mechanically or physically destroyed and can bear the impact of wire bonding. Note that it is sufficient that even when a part of a wire material which is crushed and spread due to wire bonding is present above the cavity 17, the drain pad 8 above the cavity 17 is not destroyed.

Further, etching reaches a back surface of the drain pad 8, and the cavities 17 are formed not only in the substrate 1 but also in the epitaxial layer 2. Accordingly, the parasitic capacitance can further be reduced. However, even when the thin epitaxial layer 2 is left, the parasitic capacitance can sufficiently be reduced.

### Second Embodiment

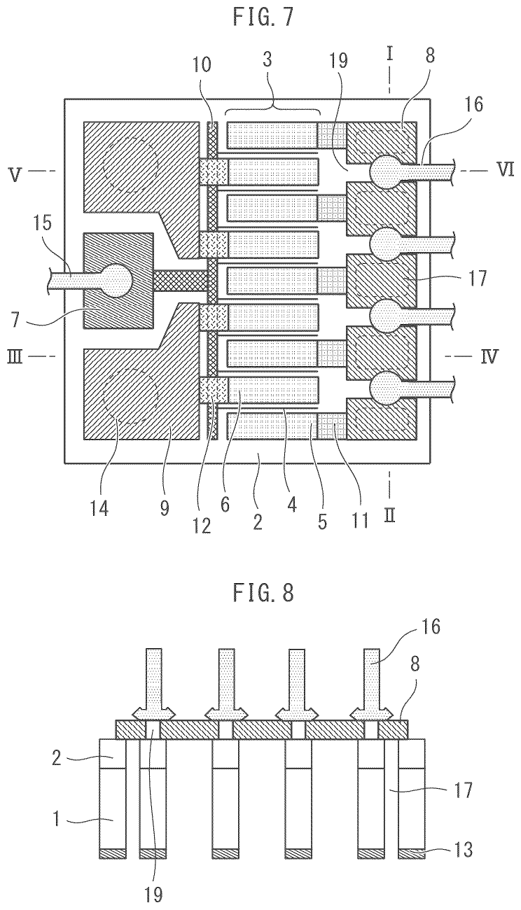

FIG. 7 is a plan view illustrating a semiconductor device according to a second embodiment. FIG. 8 is a cross-sectional view taken along I-II in FIG. 7. The drain pad 8 is divided into a plurality of pads by slits 19. The wires 16 are bonded to the drain pads 8 across the slits 19. An internal portion of the slit 19 has air or a vacuum. Accordingly, while substrate strength against wire bonding is secured, the parasitic capacitance between the drain pads 8 and the back surface electrode 13 can be reduced. Other configurations and effects are similar to those of the first embodiment.

### Third Embodiment

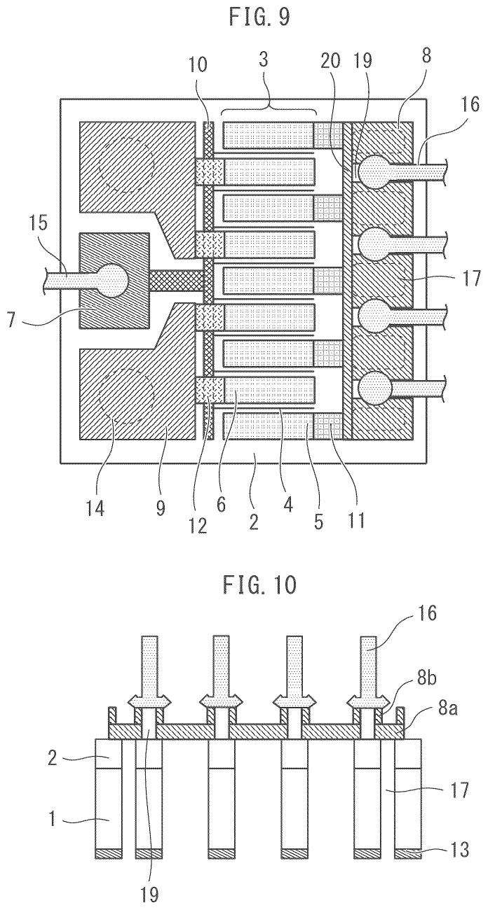

FIG. 9 is a plan view illustrating a semiconductor device according to a third embodiment. Because the drain pad 8 is divided into the plurality of pads in the second embodiment, probing has to be performed for the drain pads 8 with a plurality of probes in electric characteristic evaluation or a wafer test during wafer processing. On the other hand, in the present embodiment, the plurality of pads of the drain pad 8, which are divided by the slits 19, are connected to each other by narrow wiring 20. Accordingly, because probing can be performed with one probe for the drain pads 8, a test becomes easy. Other configurations and effects are similar to those of the second embodiment.

### Fourth Embodiment

FIG. 10 is a cross-sectional view illustrating a semiconductor device according to a fourth embodiment. FIG. 10 corresponds to the cross-sectional view taken along I-II in FIG. 7. Each of pads of the drain pad 8 which are divided by the slits 19 has a base portion 8a and protrusion portions 8b formed on a peripheral portion of the base portion 8a. The base portion 8a and the protrusion portions 8b are collectively formed by Au plating.

The wire 16 is bonded to the protrusion portions 8b arranged on both sides of the slit 19. A height of the slit 19 is approximately 10 μm in the second embodiment and is approximately 15 μm in the present embodiment. Consequently, the height of the slit 19 can be made higher. The parasitic capacitance mainly results from series connection of capacitors in portions of the slits 19 and capacitors in portions in the substrate 1. Because the permittivity of the slit 19 is approximately 1/10 the permittivity of the substrate 1, a large capacitance reduction effect can be expected only by making the slit 19 slightly higher. Further, because only the peripheral surface of the pad is thickened, an amount of an Au material can be cut down compared to a case where the whole pad is thickened.

Further, in a case where the protrusion portions 8b are formed at the same time as the air-bridge wiring 11 which connects the drain electrodes 5 to the drain pads 8 is formed, a plating time can be shortened. In this case, a thickness of the protrusion portion 8b in a portion which is not crushed by wire bonding becomes the same as a thickness of a material of the air-bridge wiring 11. Other configurations and effects are similar to those of the second or third embodiment.

### Fifth Embodiment

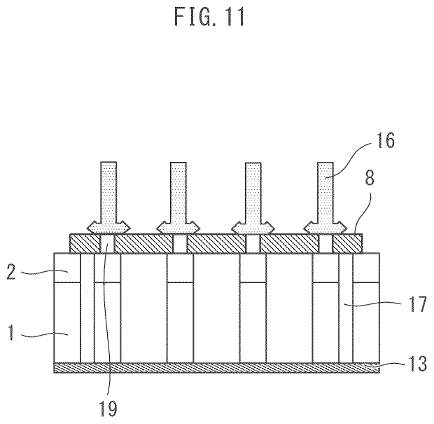

FIG. 11 is a cross-sectional view illustrating a semiconductor device according to a fifth embodiment. FIG. 11 corresponds to the cross-sectional view taken along I-II in FIG. 7. The back surface electrode 13 is formed on the whole back surface of the substrate 1. For example, a wafer-like metal plate as the back surface electrode 13 is press-bonded to the back surface of the wafer-like substrate 1 by using Au particles. The back surface electrode 13 blocks the cavities 17, and a conductive resin or solder can thereby be prevented from entering the cavities 17 in mounting. Other configurations and effects are similar to those of the first to fourth embodiments.

### REFERENCE SIGNS LIST

1 substrate; 2 epitaxial layer; 3 field effect transistor; 5 drain electrode; 6 source electrode; 8 drain pad; 8a base portion; 8b protrusion portion; 11 air-bridge wiring; 13 back surface electrode; 16 wire; 17 cavity; 19 slit; 20 wiring

1. A semiconductor device comprising:
a substrate;
an epitaxial layer formed on the substrate;
a field effect transistor formed on the epitaxial layer;
a drain pad formed on the epitaxial layer and connected to a drain electrode of the field effect transistor;
a back surface electrode formed on a back surface of the substrate and connected to a source electrode of the field effect transistor; and
a wire bonded to the drain pad,
wherein a cavity is formed in the substrate directly below the drain pad, and
the cavity is not formed directly below a bonding portion of the wire.

2. The semiconductor device according to claim 1, wherein the cavity is formed in the substrate and the epitaxial layer.

3. The semiconductor device according to claim 1, wherein the drain pad is divided into a plurality of pads by slits, and
the wire is bonded to the drain pad across the slit.

4. The semiconductor device according to claim 3, wherein the plurality of pads are connected to each other by wiring.

5. The semiconductor device according to claim 3, wherein each of the plurality of pads has a base portion and a protrusion portion formed on a peripheral portion of the base portion, and
the wire is bonded to the protrusion portions arranged on both sides of the slit.

6. The semiconductor device according to claim 5, further comprising air-bridge wiring connecting the drain pad and the drain electrode,
wherein a thickness of the protrusion portion in a portion which is not crushed by wire bonding is same as a thickness of a material of the air-bridge wiring.

7. The semiconductor device according to claim 1, wherein the back surface electrode blocks the cavity.
